(19) United States
(12) Patent Application Publication
(10) Pub. No.: US 2021/0074919 A1
(43) Pub. Date: Mar. 11, 2021

(54) VAPOR DEPOSITION MASK AND METHOD FOR MANUFACTURING VAPOR DEPOSITION MASK

(71) Applicant: Japan Display Inc., Tokyo (JP)

(72) Inventor: Jun FUJIYOSHI, Tokyo (JP)

(21) Appl. No.: 17/014,653

(22) Filed: Sep. 8, 2020

(30) Foreign Application Priority Data
Sep. 11, 2019 (JP) 2019-165584

(51) Int. Cl. H01L 51/00; C23C 14/04; H01L 51/50; H01L 51/56

(52) U.S. Cl. CPC H01L 51/0011; C23C 14/042; H01L 51/0018; H01L 51/56; H01L 51/5012

(57) ABSTRACT

A vapor deposition mask includes a mask body having a first surface and a second surface opposite to the first surface, and a holding frame connected to the first surface. The mask body is arranged with a mask pattern region having at least one opening, and a peripheral region surrounding the mask pattern region and having at least one hole or concave part on the second surface side.

### CROSS REFERENCES TO RELATED APPLICATIONS

This application is based upon and claims the benefit of priority from the prior Japanese Application No. 2019-165584, filed on Sep. 11, 2019, the entire contents of which are incorporated herein by reference.

### FIELD

One embodiment of the present invention relates to a vapor deposition mask and a method of manufacturing the vapor deposition mask. In particular, one embodiment relates to a vapor deposition mask with a thin film mask body and a process for manufacturing the vapor deposition mask.

### BACKGROUND

In the display device, a light emitting element is provided in each pixel, and an image is displayed by controlling the light emission individually. For example, in organic EL display device using an organic EL element as the light emitting element, the organic EL element is provided in each pixel, and the organic EL element has a structure in which a layer containing an organic EL material (hereinafter referred to as “organic EL layer”) is sandwiched between a pair of electrodes consisting of a anode electrode and a cathode electrode. Organic EL layer is composed of a functional layer such as light emitting layer, an electron injecting layer, and a hole injecting layer, and can emit light with colors of various wavelengths by selecting these organic materials.

A vacuum deposition method is used for forming thin film of organic EL element using a low-molecular compound as a material. In the vacuum deposition method, the vapor deposition materials are sublimated by heating them with heater in high vacuum, and the deposition materials are deposited (vapor deposition) on the surfaces of substrate to form a thin film. At this time, by using a mask (vapor deposition mask) having a large number of fine opening patterns, a high-definition thin film pattern is formed through the opening of the mask.

The deposition mask is classified into a fine metal mask (FMM) which is patterned by etching and an electrofine forming mask (EFM) which uses electroforming technology, depending on the manufacturing method. For example, Japanese Unexamined Patent Application Publication No. 2017-210633 discloses a method in which a mask portion having a high-definition opening pattern is formed using an electroforming technique, and the mask portion is fixed to the frame body portion using an electroforming technique.

### SUMMARY

A vapor deposition mask in an embodiment according to the present invention includes a mask body having a first surface and a second surface opposite to the first surface, and a holding frame connected to the first surface. The mask body is arranged with a mask pattern region having at least one opening, and a peripheral region surrounding the mask pattern region and having at least one hole or concave part on the second surface side.

A method for manufacturing vapor deposition masks in an embodiment according to the present invention includes forming a first resist pattern in a region corresponding to a mask pattern region of a substrate and a second resist pattern in a region corresponding to a peripheral region surrounding the mask pattern region of the substrate, forming a mask body formed of a metal layer on the substrate, the mask body has at least one opening formed by the first resist pattern, and has at least one hole or concave part formed by the second resist pattern, forming an insulating layer exposing an outer peripheral of the mask body and covering the at least one opening, arranging a holding frame on the outer peripheral of the mask body, forming a connecting member between the mask body and the holding frame, removing the insulating layer, and peeling the substrate from the mask body.

### BRIEF DESCRIPTION OF THE DRAWINGS

FIG. 1 is a top view of a vapor deposition device according to an embodiment of the present invention;

FIG. 2 is a side view of a vapor deposition device according to an embodiment of the present invention;

FIG. 3 is a cross-sectional view of a deposition source according to an embodiment of the present invention;

FIG. 4 is a top view of a vapor deposition mask according to an embodiment of the present invention;

FIG. 5 is a cross-sectional view of a vapor deposition mask according to an embodiment of the present invention;

FIG. 6 is a cross-sectional view showing a method for manufacturing vapor deposition mask according to an embodiment of the present invention;

FIG. 7 is a cross-sectional view showing a method for manufacturing vapor deposition mask according to an embodiment of the present invention;

FIG. 8 is a cross-sectional view showing a method for manufacturing vapor deposition mask according to an embodiment of the present invention;

FIG. 9 is a cross-sectional view showing a method for manufacturing vapor deposition mask according to an embodiment of the present invention;

FIG. 10 is a cross-sectional view showing a method for manufacturing vapor deposition mask according to an embodiment of the present invention;

FIG. 11 is a cross-sectional view showing a method for manufacturing vapor deposition mask according to an embodiment of the present invention;

FIG. 12 is a cross-sectional view showing a method for manufacturing vapor deposition mask according to an embodiment of the present invention;

FIG. 13 is a cross-sectional view showing a method for manufacturing vapor deposition mask according to an embodiment of the present invention;

FIG. 14 is a cross-sectional view showing a deposition process using vapor deposition mask according to an embodiment of the present invention;

FIG. 15 is a cross-sectional view showing a deposition process using vapor deposition mask according to an embodiment of the present invention;

FIG. 16 is a cross-sectional view showing a deposition process using vapor deposition mask according to an embodiment of the present invention;

FIG. 17 is a cross-sectional view showing a deposition process using vapor deposition mask according to an embodiment of the present invention;

FIG. 18 is a cross-sectional view showing a deposition process using vapor deposition mask according to an embodiment of the present invention;

FIG. 19 is a top view of vapor deposition mask according to an embodiment of the present invention;

FIG. 20 is a cross-sectional view of vapor deposition mask according to an embodiment of the present invention;

FIG. 21 is a cross-sectional view showing a method for manufacturing vapor deposition mask according to an embodiment of the present invention; and

FIG. 22 is a cross-sectional view showing a deposition process using a vapor deposition mask according to an embodiment of the present invention.

### DESCRIPTION OF EMBODIMENTS

Embodiments of the present invention will be described below with reference to the drawings and the like. However, one embodiment of the present invention can be implemented in various modes without departing from the gist thereof, and should not be construed as being limited to the description of the following exemplary embodiments.

In order to make the description clearer, the drawings may be schematically shown with respect to width, thickness, shape, and the like of the respective portion in comparison with the actual embodiments. However, the examples shown in the drawings are merely illustrative and do not limit the interpretation of one embodiment of the present invention. In this specification and each of the drawings, the same reference numerals are assigned to the same components as those described above with reference to the above mentioned drawings, and detailed description thereof may be omitted as appropriate.

In the present specification and claims, when expressing an aspect in which another structure is disposed on a structure, it is defined to include both a case in which another structure is disposed directly above the structure so as to be in contact with the structure, and a case in which another structure is disposed above the structure via yet another structure, unless otherwise specified.

The vapor deposition mask disclosed in the Japanese Unexamined Patent Application Publication 2017-210633 suppress the generation of strain of frame body due to thermal expansion by reducing the difference in the amount of expansion due to heat at the respective portions of the frame body. However, if the alignment accuracy of the vapor deposition mask with respect to substrate is poor, the yield of the products will be reduced. Further, if a long time is required for alignment of the vapor deposition mask, the productivity of the product will be reduced.

One embodiment of the present invention is to provide a vapor deposition mask with improved deposition position accuracy and productivity.

### First Embodiment

### [Configuration of a Vapor Deposition Device 10]

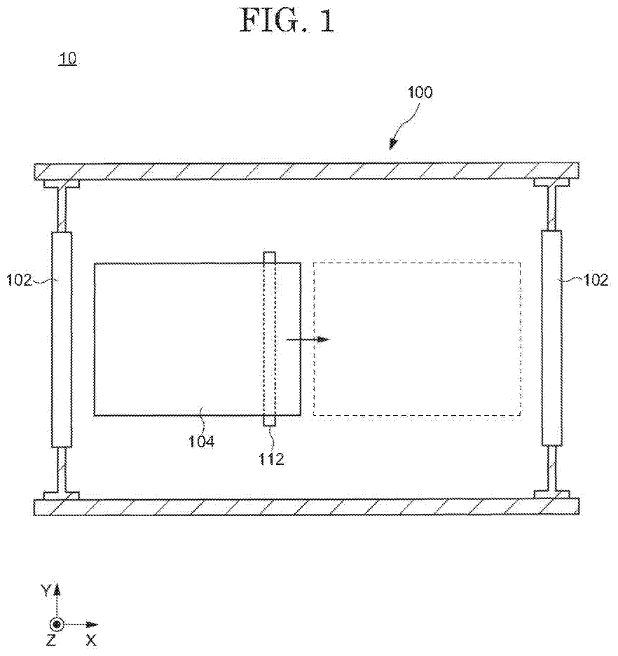

With reference to FIGS. 1 to 3, a description will be given of the configuration of a vapor deposition device 10. The vapor deposition device 10 includes a plurality of chambers having various functions. The example shown below is an example showing a deposition chamber 100 of one of the plurality of chambers.

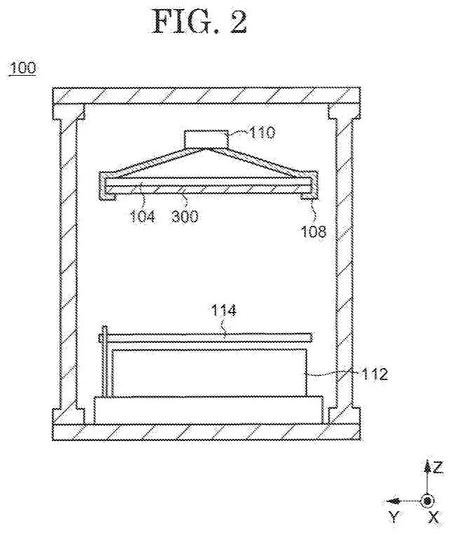

FIG. 1 is a top view of the vapor deposition device according to an embodiment of the present disclosure. FIG. 2 is a side view of the vapor deposition device according to an embodiment of the present invention.

As shown in FIG. 1, the deposition chamber 100 is partitioned from the adjacent chamber by a gate valve 102. The deposition chamber 100 can be maintained in a state in which the interior of the deposition chamber 100 is under a high vacuum reduced pressure state or filled with an inert gas such as nitrogen or argon. Therefore, such as a decompression device or a gas intake and exhaust mechanism and the like (not shown) may be connected to the deposition chamber 100.

The deposition chamber 100 has a configuration capable of accommodating an object on which a vapor deposition film is formed. Hereinafter, an embodiment in which the plate-like substrate 104 is used as the object will be described. As shown in FIGS. 1 and 2, a deposition source 112 is disposed below substrate 104. The deposition source 112 is generally rectangular in shape and is positioned along one side of the substrate 104. Such deposition source 112 is referred to as a linear source type. If the linear source type deposition source 112 is used, the deposition chamber 100 has a configuration in which the substrate 104 moves relative to the deposition source 112. FIG. 1 shows an example in which the deposition source 112 is fixed, and the substrate 104 moves thereon, but the relationship may be reversed.

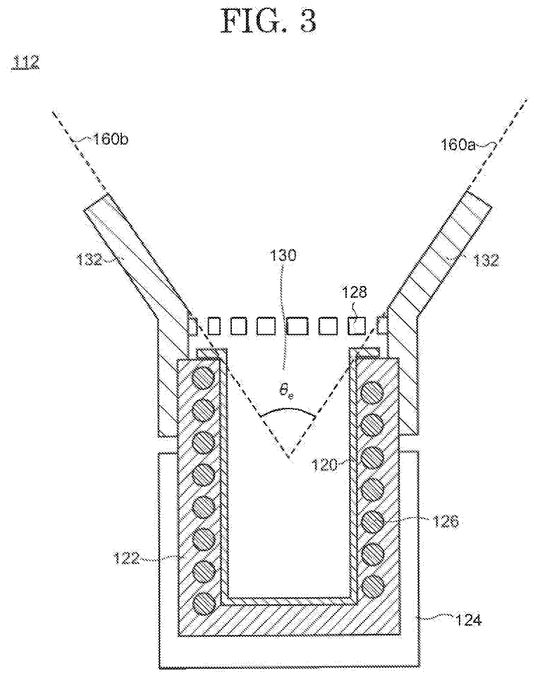

The deposition source 112 is filled with a material to be vapor-deposited (hereinafter referred to as “vapor deposition material”). Deposition source 112 has a heating unit 122 for heating the vapor deposition material (see FIG. 3 to be described later). When the vapor deposition material is heated by the heating unit 122 of the deposition source 112, the heated vapor deposition material is vaporized (sublimated), becomes vapor, and moves from the deposition source 112 toward the substrate 104. When vapor of the deposition material reaches the surface of the substrate 104, the vapor is cooled and solidified, and the vapor deposition material is deposited on the surface of the substrate 104. In this way, a thin film of the vapor deposition material is formed on the substrate 104 (on the lower surface of the substrate 104 in FIG. 2).

As shown in FIG. 2, the deposition chamber 100 further includes a holder 108 for holding the substrate 104 and the vapor deposition mask 300, a moving mechanism 110 for moving the holder 108, and a shutter 114 for shielding the upper surface of the deposition source 112. Holder 108 maintains the positional relationship between the substrate 104 and the vapor deposition mask 300. Moving mechanism 110 moves the substrate 104 and vapor deposition mask 300 over deposition source 112. Shutter 114 is movably disposed above the deposition source 112. When the shutter 114 is moved to a position overlapping on the deposition source 112, the shutter 114 shields the vapor of the deposition material heated by the deposition source 112. When the shutter 114 is moved to a position where it does not overlap with the deposition source 112, the vapor of the deposition material can reach the substrate 104 without being blocked by the shutter 114. The opening and closing of the shutter 114 can be controlled by a control device (not shown).

Although the example shown in FIGS. 1 and 2 shows a linear source type of deposition source 112, the deposition source 112 is not limited to the above shape, and it can have any shape. For example, the shape of the deposition source 112 may be a shape so-called point source type in which the material used for deposition is selectively disposed at and near by the center of gravity of substrate 104. In the case of the point source type, a mechanism for rotating substrate 104 is provided in the deposition chamber 100 with a fixed relative position between the substrate 104 and the deposition source 112. In the example shown in FIGS. 1 and 2, the horizontal vapor deposition device for placing substrate so that the main surface of the substrate is parallel to the horizontal plane. However, it can also be used in the vertical vapor deposition device for placing substrate so that the main surface of the substrate is perpendicular to the horizontal plane.

FIG. 3 is a cross-sectional view of a deposition source according to an embodiment of the present disclosure. Deposition source 112 includes a storage container 120, the heating unit 122, the vapor deposition holder 124, a mesh-shaped metallic plate 128, and a pair of guide plates 132.

The container 120 is a member for holding vapor deposition materials. As the storage container 120, for example, a member such as a crucible can be used. The storage container 120 is detachably held in the heating unit 122. The container 120 may include, for example, a metal such as tungsten, tantalum, molybdenum, titanium, or nickel, or an alloy composed of these metals. The container 120 may include an inorganic insulator such as aluminum oxide, boron nitride, or zirconium oxide and the like.

Heating unit 122 in the interior of the vapor deposition holder 124 is detachably held. The heating unit 122 is configured to heat the storage container 120 by a resistance heating method. Specifically, the heating unit 122 has a heater 126. By energizing the heater 126, the heating unit 122 is heated, and the vapor deposition material in the storage container 120 is heated and vaporized. The vaporized vapor deposition material is released from the opening 130 of the storage container 120 to the outside of the storage container 120. The mesh-like metallic plate 128 disposed so as to cover the opening 130 suppresses the ejection of the bumped vapor deposition materials out of the storage container 120. The heating unit 122 and the vapor deposition holder 124 may include the same material as the container 120.

The pair of guide plates 132 is provided on the top of the deposition source 112. At least a part of the guiding plate 132 is inclined with respect to the side surface or vertical direction of the storage container 120. By the slope of the guide plate 132, the angle at which the vapor of the vapor deposition material spreads (hereinafter, referred to as an injection angle) is controlled, so that the vapor can have directivity in the flying direction. The injection angle is determined by the angle θe formed by the two guide plates 132. The angle θe is appropriately adjusted depending on the size of substrate 104 and the distance between the deposition source 112 and the substrate 104. The angle θe is, for example, 40° or more and 80° or less, preferably 50° or more and 70° or less. In the present embodiment, the angle θe is 60°. The surfaces formed by the inclined surfaces of the guide plate 132 are the critical surfaces 160a and 160b. The vapor of the vapor deposition material flies substantially in the space sandwiched between the critical interfaces 160a and 160b. Although not shown, when the deposition source 112 is a point source, the guide plate 132 may be provided in a conical shape.

The vapor deposition material may be selected from a variety of materials and may be either the organic compound or the inorganic compound. As the organic compound, for example, a light-emitting material or a carrier-transporting material can be used. As the inorganic compound, a metal, an alloy, a metal oxide, or the like can be used. A plurality of materials may be filled in one storage container 120, and a plurality of materials may be mixed when vaporized. Although not shown, using a plurality of deposition sources may be configured so that different vapor deposition materials can be deposited at the same time.

### [Configuration of the Vapor Deposition Mask 300]

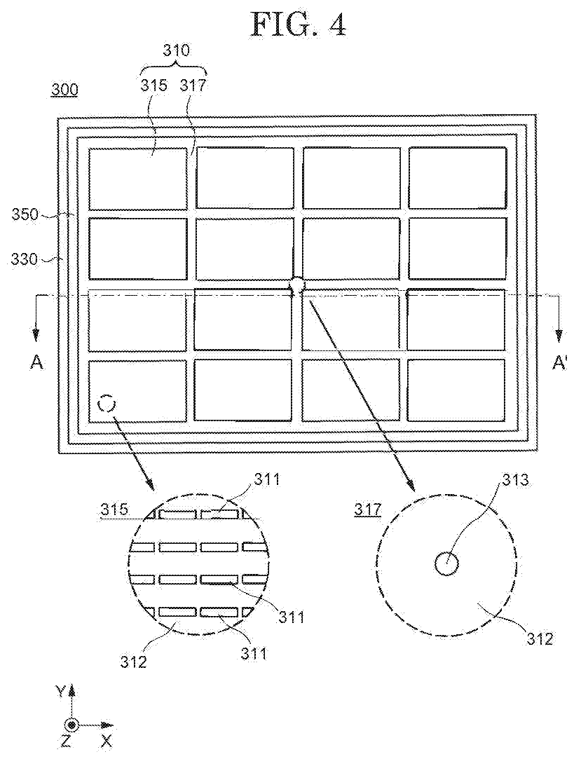

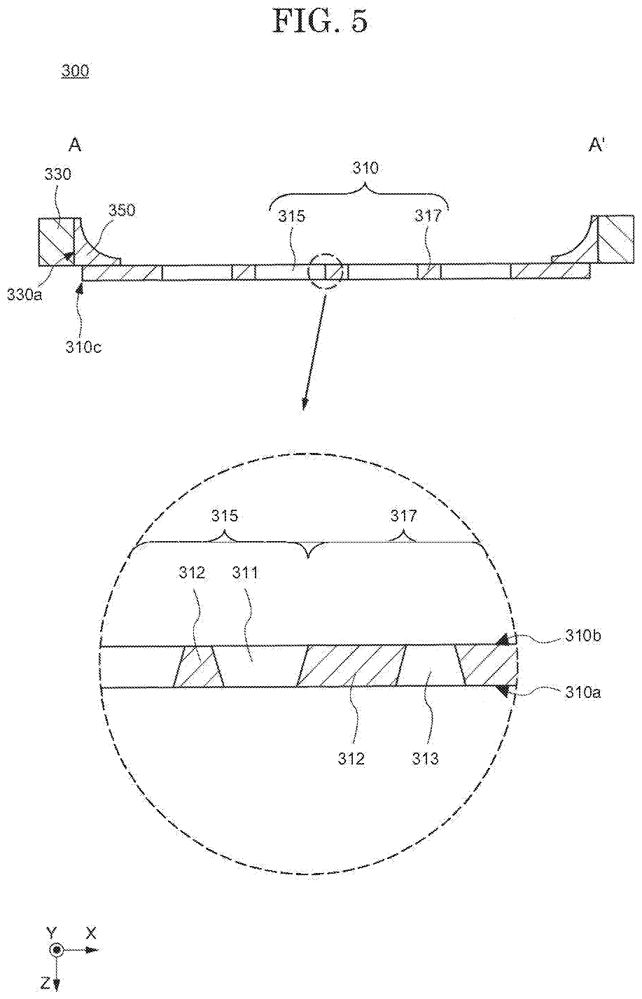

The configuration of a vapor deposition mask according to an embodiment of the present invention will be described with reference to FIGS. 4 to 5. FIG. 4 is a top view of vapor deposition mask according to an embodiment of the present disclosure. FIG. 5 is a cross-sectional view of vapor deposition mask according to an embodiment of the present disclosure. Cross-sectional view shown in FIG. 5 is cross-sectional view along A-A′ line in FIG. 4. The vapor deposition mask 300 has a mask body 310 in the form of a thin film, a holding frame 330, and a connection member 350.

A plurality of mask pattern regions 315 and peripheral region 317 around each mask pattern region 315 are arranged on the mask body 310. When depositing the organic EL material on the substrate 104, each mask pattern region 315 of the mask body 310 is disposed so as to correspond to the display region of the display device. Peripheral region 317 of the masking body 310 is arranged to correspond to the peripheral region of the display device. The masking body 310 has a first surface 310a located on the substrate 104 side during the deposition and a second surface 310b opposed to the first surface 310a. The second surface 310b of the mask body 310 is fixed to the holding frame 330 via connection member 350.

In each mask pattern region 315, a plurality of openings 311 penetrating the mask body 310 are provided in accordance with the pixel pitch of the display device. The region other than the opening 311 of the masked body 310 is called a non-opening region 312. The non-opening region 312 surrounds each opening 311. Non-opening region 312 corresponds to the portion of each mask pattern region 315 that shields the vapor deposition material.

During deposition, alignment of the vapor deposition mask 300 and substrate 104 is performed so that the opening 311 corresponds to the deposition region (region to be formed thin film) on the substrate 104 and the non-opening region 312 and the non-deposition region on the substrate 104 overlaps. The vapor of the vapor deposition material reaches the substrate 104 through the opening 311, thereby depositing the vapor deposition material on the deposition region to form a thin film.

In the present embodiment, the diameter of the opening end of opening 311 on the first surface 310a side is smaller than the diameter of the opening end on the second surface 310b side. In the opening 311, the diameter of the opening end on the first surface 310a side is the smallest, and the diameter of the opening end on the second surface 310b side is the largest. In other words, the opening 311 has a tapered configuration in which the diameter linearly changes in the deposition direction (Z direction from the second surface 310b to the first surface 310a). Since the opening 311 has a reverse-tapered configuration at the first surface 310a (reverse Z-direction from the first surface 310a side to the second surface 310b side), the vapor deposition materials can be suppressed from circulating under the mask. However, the configuration of the opening 311 is not limited thereto, and the diameter of the opening end on the first surface 310a side and the diameter of the opening end on the second surface 310b side may be substantially the same. Since the opening 311 has such construction, thin film having a fine pattern can be deposited.

In the present embodiment, peripheral region 317 is provided with a hole part 313 which is a through hole. During deposition, the alignment spacer for alignment of substrate 104 to be described later is fitted to the hole part 313, and the alignment of the vapor deposition mask 300 and the substrate 104 is performed. The hole part 313 is blocked by fitting the alignment spacer. Therefore, the hole part 313 corresponds to the portion shielding the vapor deposition material in the peripheral region 317. The region other than hole part 313 of peripheral region 317 corresponds to the non-opening region 312.

In the present embodiment, the diameter of the opening end of hole part 313 on the first surface 310a side is larger than the diameter of the opening end on the second surface 310b side. In the hole part 313, the diameter of the opening end on the first surface 310a side is the largest, and the diameter of the opening end on the second surface 310b side is the smallest. In other words, hole part 313 has a tapered configuration in which the diameter linearly changes in the direction in which the alignment spacer is fitted, i.e., in the reverse Z direction from the first surface 310a side to the second surface 310b side. Since the hole part 313 has a tapered configuration at the first surface 310a (reverse Z-direction from the first surface 310a side to the second surface 310b side), the hole part 313 and the alignment spacer can be easily fitted to each other, and the position of the masking body 310 and substrate 104 can be easily aligned with each other. Also, the alignment spacers have same tapered configuration so that the distances between the masking body 310 and substrate 104 can be adjusted. Since the contact area between hole part 313 and the alignment spacer is large, the dust generation from scratches on the alignment spacer can be suppressed by dispersing the load applied to the alignment spacer, thereby improving productivity. However, the configuration of the hole part 313 is not limited thereto, and the diameter of the opening end on the first surface 310a side and the diameter of the opening end on the second surface 310b side may be substantially the same. Since hole part 313 has such configuration, peripheral region 317 can be narrowed.

In the present embodiment, the hole part 313 is circular in the planar view. That is, the hole part 313 is a truncated cone-shaped through hole. Such configuration of the hole part 313 facilitates the fitting of the hole part 313 and the alignment spacer, and the position of the mask body 310 and the substrate 104 are easily aligned. In addition, since the hole part 313 does not have any corner, dust generation from scratches of the alignment spacer can be suppressed by dispersing stresses applied to the alignment spacer, and productivity can be improved. However, one embodiment of the present invention is not limited thereto, and the hole part 313 may have a polygonal shape in the planar view. The hole part 313 may be a truncated pyramid shaped through hole. By hole part 313 has a corner portion, it is possible to align the positional deviation of the masking body 310 and substrate 104 in the rotational direction of the X-Z plane around the Y direction axis.

The position of the opening 311 of the mask body 310 and the deposition region of the substrate 104 is deviated due to the stress and strain of the mask body 310 itself. However, since stress and strain generally tend to affect uniformly in the entire mask body 310, the misalignment can be minimized by performing alignment with reference to the central portion of the mask body. Since the hole part 313 according to the present embodiment has the above-described configuration, it is suitable for the pre-alignment in the vicinity of the center of the masking body 310, which is a reference point of the alignment. Therefore, hole part 313 in the present embodiment is arranged near the center of the masked body 310 at the planar view. However, one embodiment of the present invention is not limited thereto, and the hole part 313 may be provided at the position other than the center of the masking body 310. In this embodiment, one hole part 313 is provided in the peripheral region 317 of the masking body 310. However, one embodiment of the present invention is not limited thereto, and a plurality of hole part 313 may be provided in the peripheral region 317 or may be provided in the non-opening region 312 of the mask pattern region 315. The deposition position accuracy can be improved by providing a plurality of hole parts 313.

The holding frame 330 and the connection member 350 are disposed on the outer periphery of the masking body 310. The connection member 350 is overlapped with the mask body 310 in a planar view, and surrounds a plurality of mask pattern regions 315, i.e., a plurality of openings 311 of mask body 310. The holding frame 330 is not overlapped with the mask body 310 in a planar view, and is provided on the extension of the second surface 310b of the mask body 310. That is, in the horizontal direction, the inner surface 330a of the holding frame 330 is provided outside the outer edge 310c of the masking body 310. The second surface 310b of the masking body 310 is fixed to the inner surface 330a of the holding frame 330 via a connection member 350. The connection member 350 is arranged in contact with the inner surface 330a of the holding frame 330 and the second surface 310b of the masking body 310. Note that the horizontal direction is a direction parallel to main surface of the masking body 310. The inner surface 330a of the holding frame 330 indicates an inner edge on the center side of the holding frame 330.

In the above configuration, the mask body 310 is a plating layer, the thickness of the mask body 310 in the Z-direction is 3 μm or more and 10 μm or less. The connection member 350 is a plating layer, and the thickness (Z direction) of the connection member 350 on the second surface 310b of the masking body 310 and the thickness (X direction) of the connection member 350 on the inner surface 330a of the holding frame 330 are preferably 50 μm or more and 2000 μm or less.

As described above, the vapor deposition mask 300 according to the present embodiment includes the hole part 313 having the structure described above, it is possible to improve the deposition position accuracy and productivity when fixing the vapor deposition mask 300 to the substrate 104 by a magnet or the like.

### [Method of Manufacturing Vapor Deposition Mask 300]

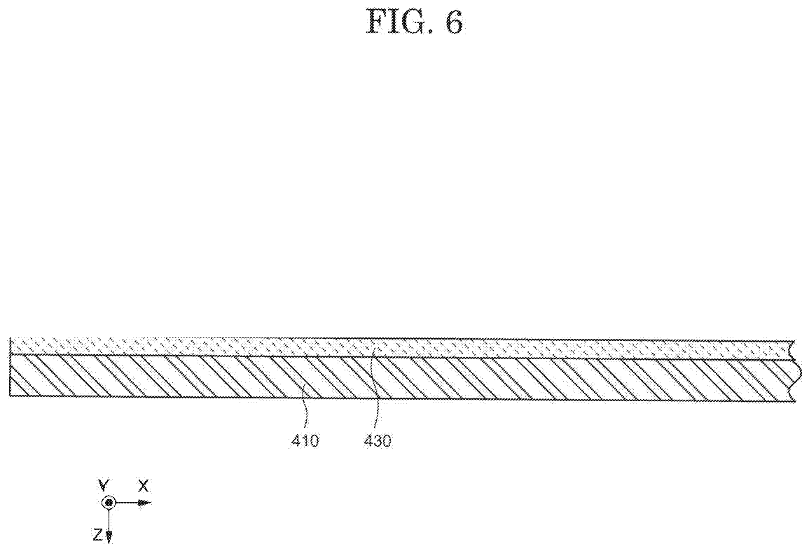

A method of manufacturing the vapor deposition mask 300 according to an embodiment of the present invention will be described with reference to FIGS. 6 to 13. FIGS. 6 to 13 are cross-sectional view showing a method of manufacturing vapor deposition mask according to an embodiment of the present invention disclosure.

FIG. 6 is a cross-sectional view showing a process of forming the conductive release layer 430 in the manufacturing process of the vapor deposition mask 300 according to the embodiment of the present disclosure. As shown in FIG. 6, the release layer 430 is formed on substantially the entire surface of the support substrate 410. As the support substrate 410, highly flat substrate is preferable, and glass substrate is particularly preferable. The thickness of the support substrate 410 may be 0.5 mm or more and 1 mm or less. As the material of the release layer 430, a metal oxide such as ITO (indium tin oxide) or IZO (indium zinc oxide), or a conductive material containing a metal such as Al (aluminum), Mo (molybdenum), Ti (titanium), Cu (copper), or Cr (chromium) is preferable. When forming the mask body 310 by electroplating, the thickness of the release layer 430 is preferably a thickness that can impart sufficient conductivity so that the metal layer can grow. For example, the thickness of the release layer 430 is preferably 50 nm or more and 500 nm or less in case of ITO.

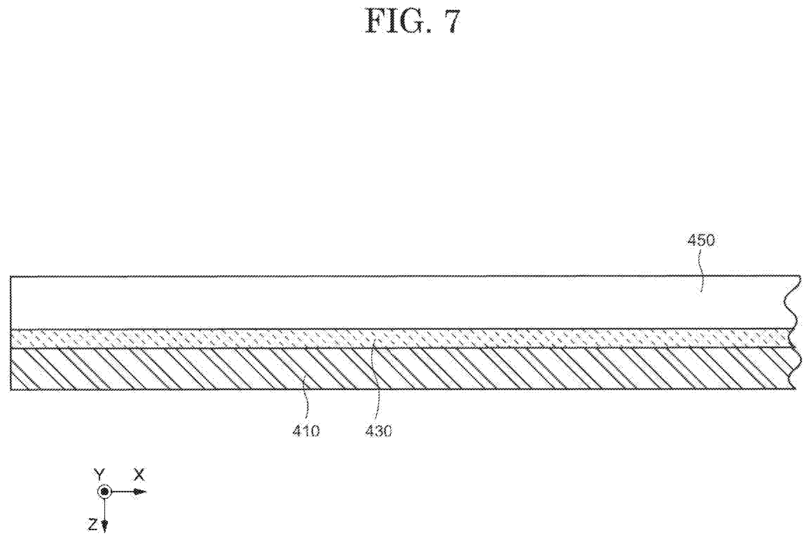

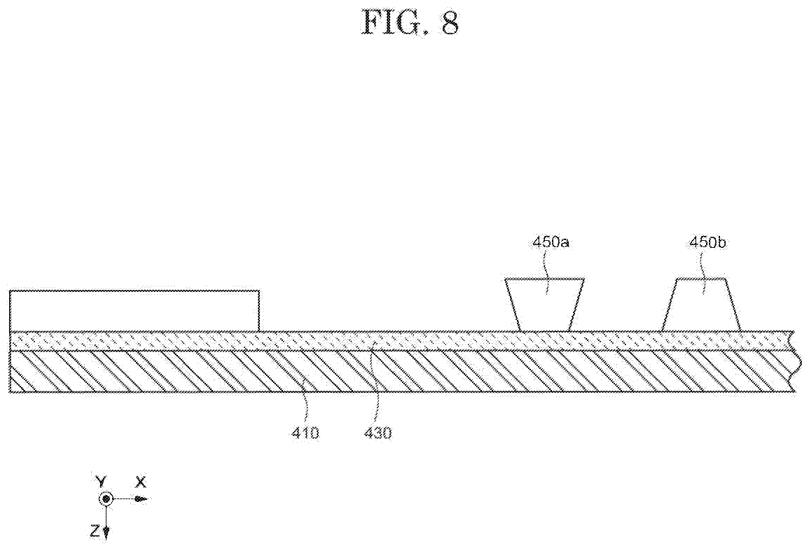

FIGS. 7 and 8 are a cross-sectional view showing a process of forming the first insulating layer 450 in the manufacturing process of the vapor deposition mask 300 according to the embodiment. As shown in FIG. 7, a photosensitive resin material is applied to substantially the entire surface of the support substrate 410, and the photosensitive resin material is patterned by photolithography and etch to form the first insulating layer 450a and 450b for forming a masking body 310 as shown in FIG. 8 (if the first insulating layer 450a and 450b are not distinguished from each other, they are simply referred to as a first insulating layer 450). The region and shape in which the first insulating layer 450 is formed corresponds to the region and shape in which the opening 311 will be formed. The first insulating layer 450a has the smallest cross-sectional area on the support substrate 410 side, and the cross-sectional area is formed so as to linearly increases with increasing distance from the support substrate 410. The region and shape in which the first insulating layer 450b (second resist pattern) is formed corresponds to the region and shape in which the hole part 313 will be formed. The first insulating layer 450b has the largest cross-sectional area on the support substrate 410 side, and the cross-sectional area is formed so as to linearly reduce with increasing distance from the support substrate 410. That is, the first insulating layer 450a is formed in an inversely tapered structure, and the first insulating layer 450b is formed in a tapered structure. The shape and height of each first insulating layer 450a and 450b can be controlled by the wavelengths of the lasers and the exposure amount.

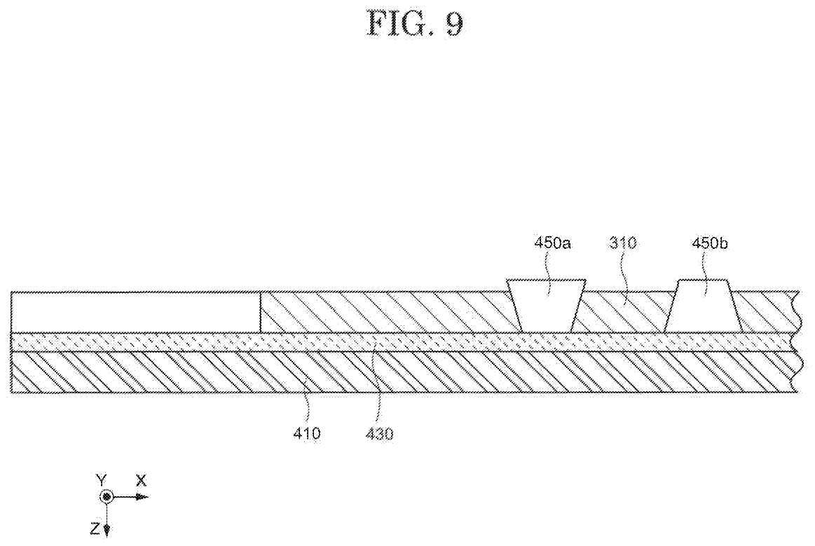

FIG. 9 is a cross-sectional view showing a method of forming a mask body 310 in a process of manufacturing a vapor deposition mask 300 according to an embodiment of the present disclosure. The mask body 310 can be selectively formed on the release layer 430 exposed from the first insulating layer 450 by an electrolytic plating method that energizes the release layer 430. However, one embodiment of the present invention is not limited to this, without the release layer 430 for example, a plating layer is formed on the first insulating layer 450 and on the exposed portion of the first insulating layer 450 by an electroless plating method, and the first insulating layer 450 is peeled to form the first insulating layer 450. The mask body 310 may be formed by removing the plating layer formed on the first insulating layer 450 (lift-off). The material of the mask body 310 is not particularly limited, for example, a magnetic material such as nickel (Ni) or a nickel alloy can be used. The thickness of the masking body 310 is preferably in the range of 3 μm or more and 10 μm or less.

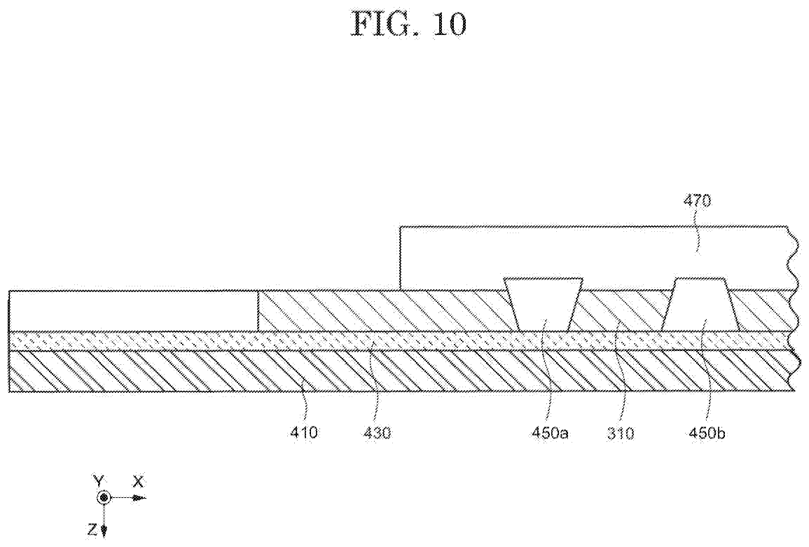

FIG. 10 is a cross-sectional view showing a method of forming the second insulating layer 470 in the process of manufacturing the vapor deposition mask 300 according to the embodiment. A photosensitive resin material is coated on substantially the entire surface of the support substrate 410, and the photosensitive resin material is patterned by photolithography and etching to form a second insulating layer (resist layer) 470 for forming connection member 350 as shown in FIG. 10. The region forming the second insulating layer 470 corresponds to the region inside the connection member 350. The connection member 350 is formed on the outer periphery of the masking body 310. Thus, the second insulating layer 470 exposes the outer periphery of the mask body 310 and covers over the plurality of mask pattern regions 315 of the mask body 310.

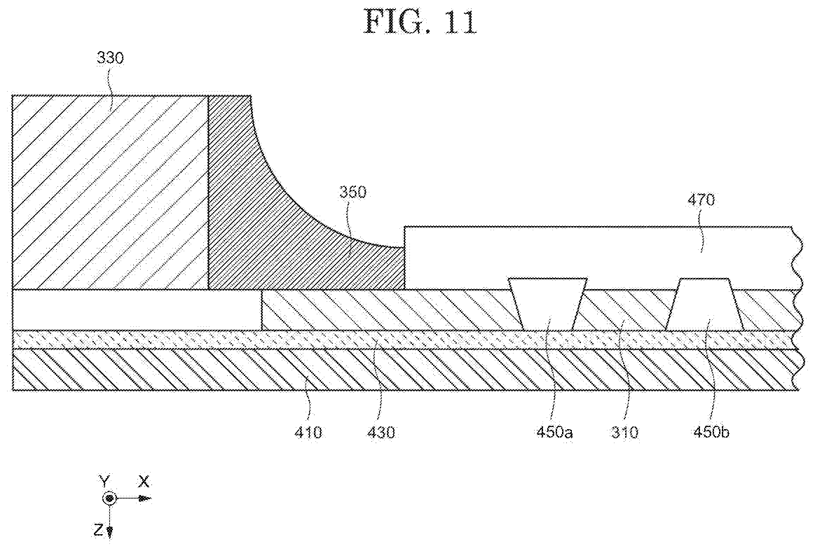

FIG. 11 is a cross-sectional view showing a process of disposing the holding frame 330 at the outer periphery of the mask body 310 and forming connection member 350 between the mask body 310 and the holding frame 330 in the manufacturing process of the vapor deposition mask 300 according to the embodiment. In the present embodiment, the holding frame 330 is a rectangular frame surrounding the plurality of mask pattern regions 315 of the mask body 310. The material of the holding frame 330 is not particularly limited as long as it has conductivity and rigidity. As a material of the holding frame 330, for example, an inver is preferably used. The thickness of the holding frame 330 is 300 μm or more and 3 mm or less, preferably 500 μm or more and 2 mm or less.

The connection member 350 can be selectively formed on the mask body 310 exposed from the second insulating layer 470 and on the holding frame 330 by an electroplating method which energizes the mask body 310 and the retaining frame 330. The material of connection member 350 is not particularly limited, and for example, a magnetic material such as nickel (Ni) or nickel alloys can be used. The thickness (in the Z direction) of the connection member 350 on the second surface 310b of the masking body 310 and the thickness (in the X direction) of the connection member 350 on the inner surface 330a of the holding frame 330 are preferably 50 μm or more and 2000 μm or less.

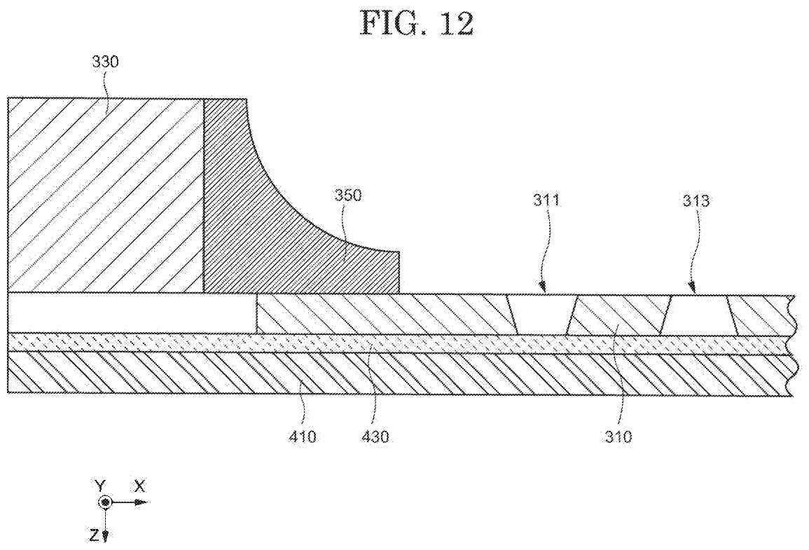

FIG. 12 is a cross-sectional view showing a process of removing the first insulating layer 450 and the second insulating layer 470 in the process of manufacturing the vapor deposition mask 300 according to an embodiment of the present disclosure. Removing the first insulating layer 450 and second insulating layer 470 exposes a portion of the mask body 310 inside the connection member 350. The opening 311 and hole part 313 are formed in respective mask pattern region 315 and peripheral region 317 of the mask body 310. The release layers 430 are exposed inside the opening 311 and hole part 313.

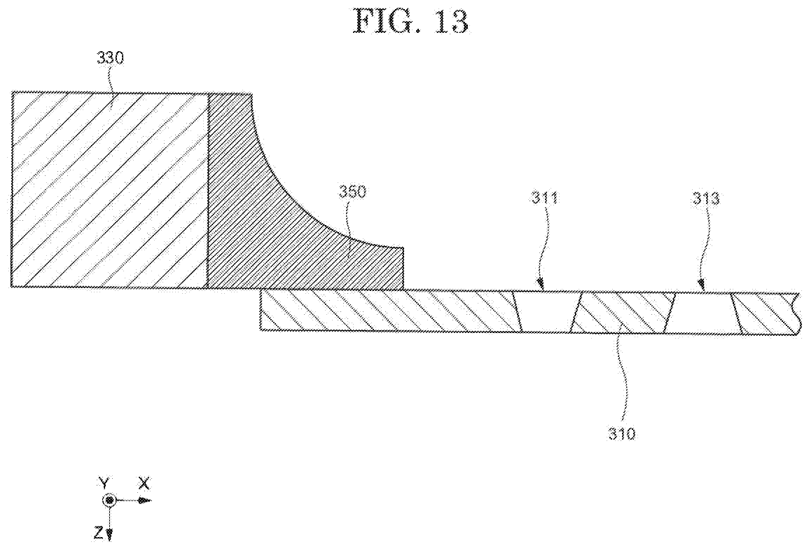

FIG. 13 is a cross-sectional view showing a process of peeling the support substrate 410 from the mask body 310 in the manufacturing process of the vapor deposition mask 300 according to the embodiment. From the condition shown in FIG. 12, the release layer 430 and support substrate 410 can be peeled off to form the vapor deposition mask 300 shown in FIG. 13.

As described above, according to the method of manufacturing the vapor deposition mask 300 according to the present embodiment, The hole part 313 is formed together with the opening 311, so that when the vapor deposition mask 300 is fixed to the substrate 104 by a magnet or the like, the deposition position accuracy and productivity can be improved.

### [Deposition Method Using a Vapor Deposition Mask 300]

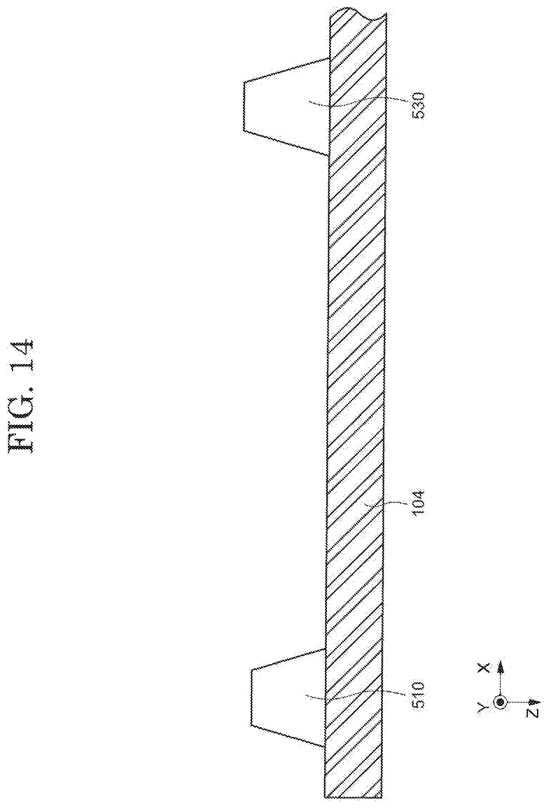

A vapor deposition method using a vapor deposition mask according to an embodiment of the present invention will be described with reference to FIGS. 14 to 18. FIGS. 14 to 18 are cross-sectional view showing deposition methods using vapor deposition mask according to an embodiment of the present disclosure.

FIG. 14 is a cross-sectional view showing a process of forming the spacer 510 and the alignment spacer 530 on the substrate 104 in the vapor deposition process using the vapor deposition mask 300 according to the embodiment. The spacer 510 and the alignment spacer 530 may be formed by the same process from the same material and may be formed by different processes from different materials. In the present embodiment, the alignment spacer 530 and the spacer 510 have a truncated cone shape, and the height of the alignment spacer 530 is higher than the height of the spacer 510. However, the shape and height of the alignment spacer 530 are not limited to this, and the shape and height of the alignment spacers 530 can be selected as appropriate according to the shape of hole part 313 of the vapor deposition mask 300 and the distance between the vapor deposition mask 300 and the substrate 104. The height of the spacer 510 can be appropriately selected in accordance with the distance between the holding frame 330 and the substrate 104.

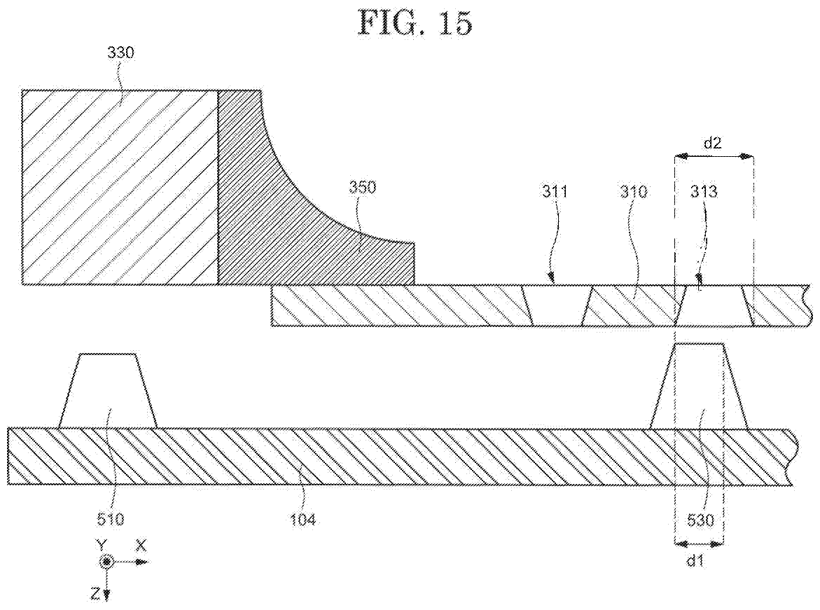

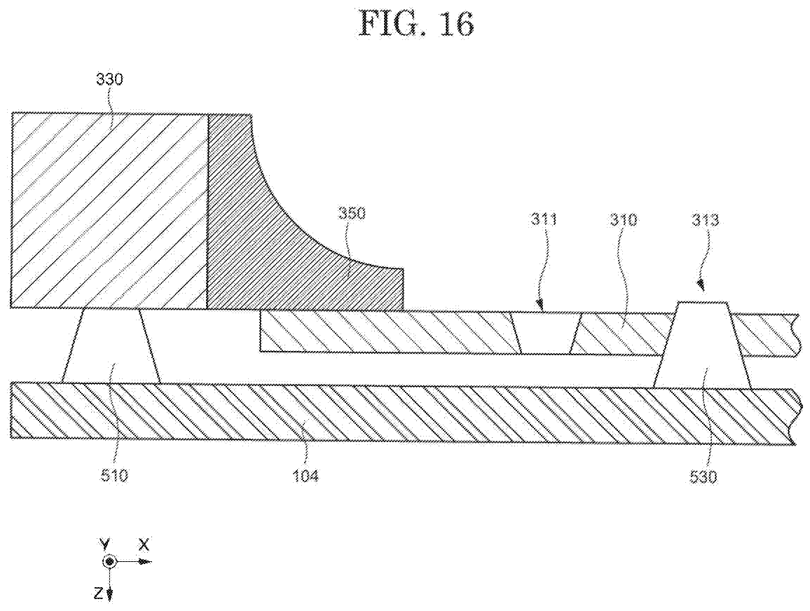

FIG. 15 and FIG. 16 are a cross-sectional view showing a process of aligning the vapor deposition mask 300 and substrate 104 in the vapor deposition process using the vapor deposition mask 300 according to the embodiment. The hole part 313 of the vapor deposition mask 300 and the alignment spacer 530 of the substrate 104 are aligned and fitted.

In the present embodiment, the diameter d1 of the upper end of the alignment spacer 530 is smaller than the diameter d2 of opening end of hole part 313 on the first surface 310a side, and the alignment spacer 530 and hole part 313 are tapered in the fitting direction (reverse Z direction from the first surface 310a side to the second surface 310b side). Since the hole part 313 and the alignment spacer 530 has such structure, even if the vapor deposition mask 300 and substrate 104 is slightly misaligned, the hole part 313 and the alignment spacer 530 can be easily fitted to each other, and the position of the mask body 310 and substrate 104 can be self-aligned (self-aligned). Further, by fitting the hole part 313 and the alignment spacer 530, the distance between the vapor deposition mask 300 and the substrate 104 can be matched. Since the contact area between the hole part 313 and the alignment spacer 530 is large, dust generation from scratches of the alignment spacer 530 can be suppressed by dispersing the load applied to the alignment spacer 530, and productivity can be improved.

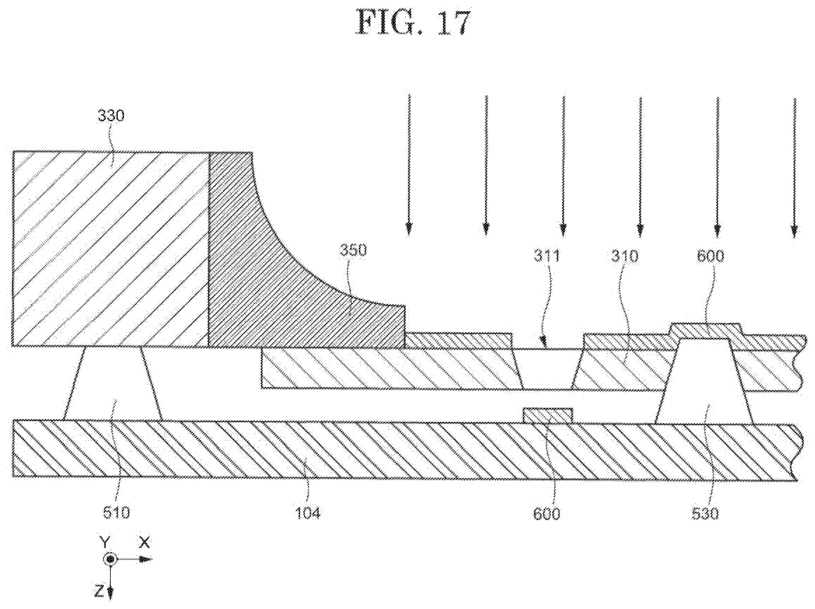

FIG. 17 is a cross-sectional view showing a process of forming a thin film on substrate 104 by vapor deposition in the vapor deposition process using the vapor deposition masks 300 according to an embodiment of the present disclosure. The vapor of the vapor deposition material passes through the opening 311 from the second surface 310b side to the first surface 310a side (arrow, Z-direction) of the vapor deposition mask 300, reaches the substrate 104, and deposits the vapor deposition material on the vapor deposition region, thereby forming the thin film 600. The deposited material deposits on the second surface 310b of the mask body 310 to form the thin film 600 in the non-opening region 312 that is shielded by the mask body 310. In the hole part 313, the vapor deposition materials are deposited on the fitting alignment spacers 530 to form the thin film 600.

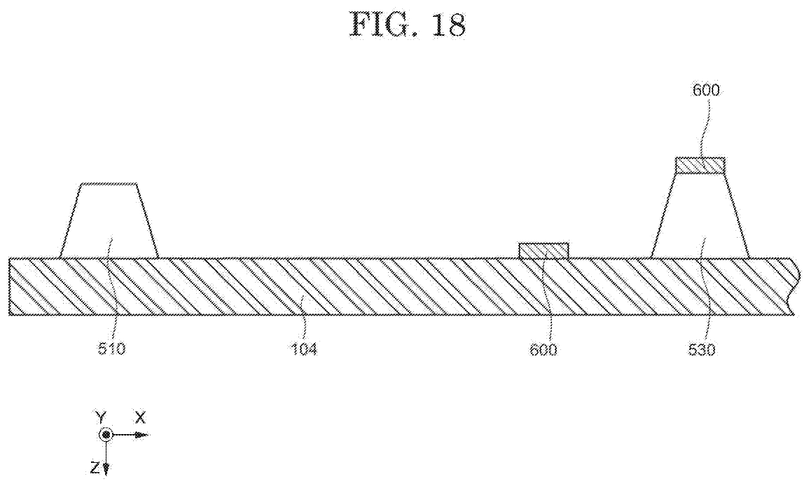

FIG. 18 is a cross-sectional view showing a process of removing the vapor deposition mask 300 from the substrate 104 in a deposition method using the vapor deposition mask 300 according to an embodiment of the present invention. Removing the vapor deposition masks 300 from the substrate 104 leaves thin film 600 over the deposition region and alignment spacers 530 of the substrate 104.

As described above, according to the deposition method using the vapor deposition mask 300 according to the present embodiment, by fitting the alignment spacer 530 and hole part 313, the deposition position accuracy and productivity can be improved. In addition to the normal optical alignment marker, the physical alignment marker including the alignment spacer 530 and the hole part 313 according to the present embodiment can further improve the deposition position accuracy.

### Second Embodiment

### [Configuration of a Vapor Deposition Mask 300A]

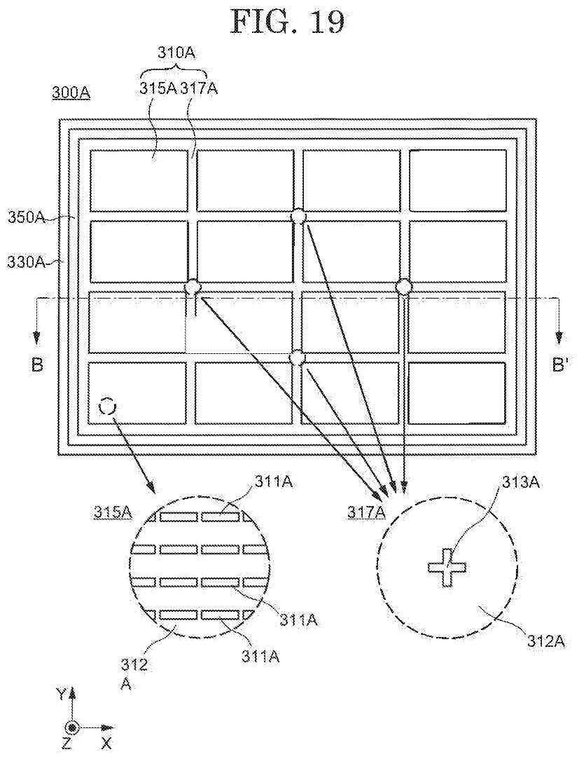

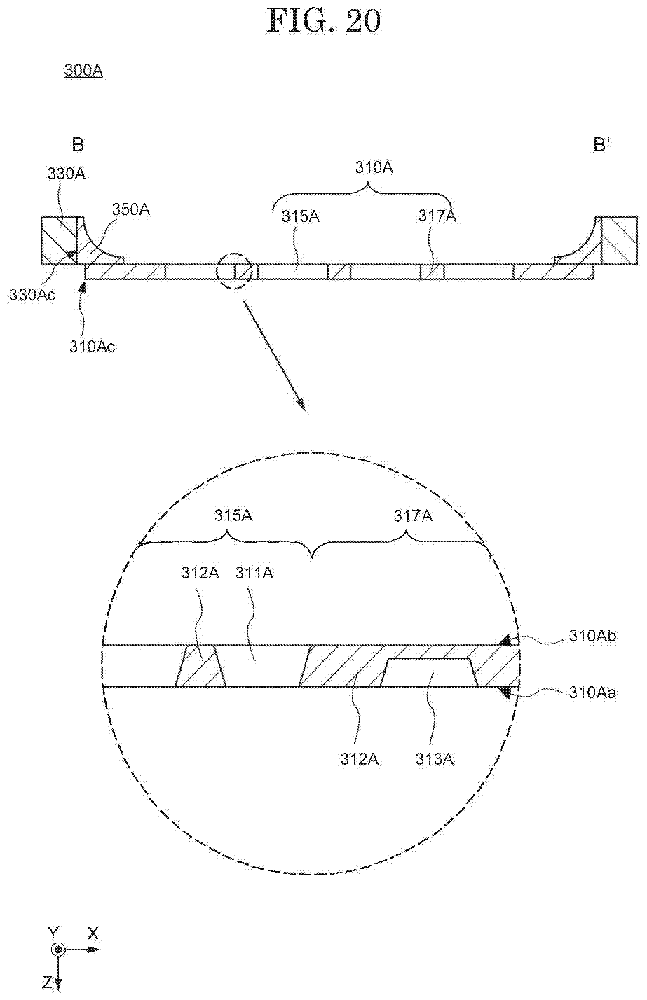

The configuration of a vapor deposition mask according to an embodiment of the present invention will be described with reference to FIG. 19. FIG. 19 is a top view of the vapor deposition mask according to an embodiment of the present disclosure. FIG. 20 is a cross-sectional view of the vapor deposition mask according to an embodiment of the present disclosure. The cross-sectional view shown in FIG. 20 is a cross-sectional view along B-B′ line of FIG. 19. In the present embodiment, since the configuration is the same as that of the first embodiment except for hole part 313A, repetitive descriptions are omitted.

In the present embodiment, the peripheral region 317A is provided with a hole part 313A which is a bottomed hole. During the vapor deposition, the hole part 313A is fitted with the alignment spacers of the substrate 104A to align the vapor deposition mask 300A with the substrate 104A. The hole part 313A corresponds to a part of peripheral region 317A that shields vapor deposition materials. The region other than the hole part 313A of peripheral region 317A also corresponds to the non-opening region 312A.

The depth of the hole part 313A in the thickness direction (reverse Z direction) of the mask body 310A is preferably in the range of 1/2 or more and 4/5 or less of the thickness of the mask body 310A. Since the depth of the hole part 313A is 1/2 or more of the thickness of the mask body 310A, the fitting between the hole part 313A and the alignment spacer is stabilized, and the positions of the mask body 310A and substrate 104A are easily aligned. Since the depth of hole part 313A is equal to or less than 4/5 of the thickness of the mask body 310A, it is possible to stably receive the load from the alignment spacer without penetrating the bottom portion of the hole part 313A (the second surface 310Ab of the mask body 310A). Such configuration of the hole part 313A allows the distances between the masking body 310A and substrate 104A to be matched.

In the present embodiment, the diameter of the opening end of the hole part 313A on the first surface 310Aa side is larger than the diameter of the closed end on the second surface 310Ab side. In other words, the hole part 313A has a taper structure in the direction in which the alignment spacer is fitted (i.e., in the reverse Z direction from the first surface 310Aa side to the second surface 310Ab side). Since the hole part 313A has such configuration, the hole part 313A and the alignment spacer are easily fitted to each other, and the positions of the masking body 310A and the substrate 104A are easily aligned with each other. Since the contacts area between the hole part 313A and the alignment spacer is large, dust generation from scratches of the alignment spacer can be suppressed by dispersing the load applied to the alignment spacer, and productivity can be improved. However, one embodiment of the present invention is not limited thereto, and the diameter of the opening end of hole part 313A on the first surface 310Aa side and the diameter of the closed end on the second surface 310Ab side may be substantially the same. Since hole part 313A has such configuration, peripheral region 317A can be narrowed.

In the present embodiment, hole part 313A has a cross shape in a planar view. The hole part 313A is a frustro-shaped bottomed hole with a cross-shaped opening end. However, one embodiment of the present invention is not limited thereto, and the hole part 313A may be T-shaped or L-shaped in the planar view. Since the hole part 313A has such configuration, the hole part 313A and the alignment spacer are hardly displaced when they are fitted, and the locations of the masking body 310A and substrate 104A are easily maintained. Further, since hole part 313A has corner portion, it is possible to align the positional deviation between the masks body 310A and substrate 104A in the rotational direction of the X-Z plane around the Y direction.

Since the hole part 313A according to the present embodiment has the above-described configuration, it is suitable for the main alignment in the vicinity of the periphery of the masked body 310A after the pre-alignment is performed. Therefore, in the present embodiment, the hole part 313A is provided in the vicinity of the periphery of the masking body 310A in planar view. However, one embodiment of the present invention is not limited thereto, and the hole part 313A may be provided near the center of the masking body 310A. In this embodiment, four hole part 313A are provided in the peripheral region 317A of the masking body 310A. However, one embodiment of the present invention is not limited thereto, and one or more hole part 313A may be provided in the peripheral region 317A, or may be provided in the non-opening region 312A of the mask pattern region 315A. By providing a plurality of hole part 313A, the accuracy of the deposition position can be further improved.

The hole part 313A according to the present embodiment preferably further combines the hole part 313 according to the first embodiment with the pre-alignment in the vicinity of the center of the masking body 310A. In planar view, the diameter of the hole part 313 located near the center of the mask body is preferably larger than the diameter of the hole part 313A located near the periphery of the mask. Here, the diameter of hole part in planar view indicates the smallest diameter of opening end of hole part in planar view. Since the hole part 313 disposed in the vicinity of the center and the hole part 313A disposed in the vicinity of the periphery have differing shapes and diameters, two stages of pre-alignment and main alignment can be performed, and the deposition position accuracy can be further improved.

As described above, according to the vapor deposition mask 300A of the present embodiment, since the hole part 313A having the above-described structures is included, when the vapor deposition mask 300A is fixed to the substrate 104A by a magnet or the like, the precision of the vapor deposition location and the productivity can be improved.

### [Method for Manufacturing Vapor Deposition Mask 300A]

The method of manufacturing the vapor deposition mask 300A according to the embodiment is the same as the method of the first embodiment except that the height of the first insulating layer 450b is formed smaller than the height of the first insulating layer 450a, and therefore the description thereof will not be repeated.

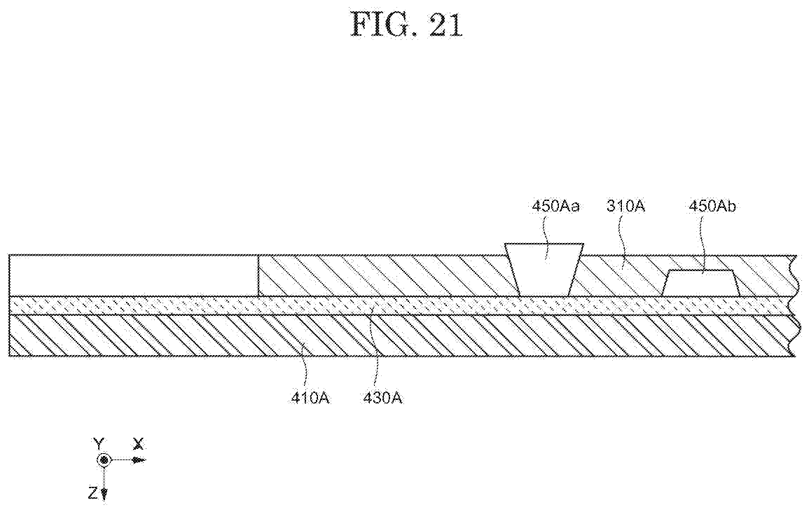

FIG. 21 is a cross-sectional view showing a process of forming a mask body 310A in the manufacturing process of the vapor deposition mask 300A according to the embodiment. In the manufacturing process of the vapor deposition mask 300A according to the present embodiment, the height of the first insulating layer 450Ab corresponding to the hole part 313A is formed smaller than the height of the first insulating layer 450Aa corresponding to the opening 311A. The height of the first insulating layer 450Ab is preferably 1/2 or more and less than 1 of the height of the first insulating layer 450Aa. The respective shapes and heights of the first insulating layer 450Aa, 450Ab can be controlled by the wavelengths and exposure amounts of the lasers. For example, by forming the first insulating layer 450Ab with an exposure amount smaller than that of the first insulating layer 450Aa, the height of the first insulating layer 450Aa can be made lower. By forming the first insulating layer 450Ab and the first insulating layer 450Aa in such structures, the mask body 310A can be formed on the first insulating layer 450 Ab, and the hole part 313A can be formed into a bottomed hole.

### [Vapor Deposition Method Using Vapor Deposition Mask 300A]

In the vapor deposition method using the vapor deposition mask 300A according to the present embodiment, it is the same as that of the first embodiment except for the height of the alignment spacer 530A, and therefore, a repetitive description thereof is omitted. Since hole part 313A of the vapor deposition mask 300A according to the embodiment of the present invention disclosure has a bottomed hole, the height of the alignment spacer 530A is formed smaller than the height of the spacer 510A.

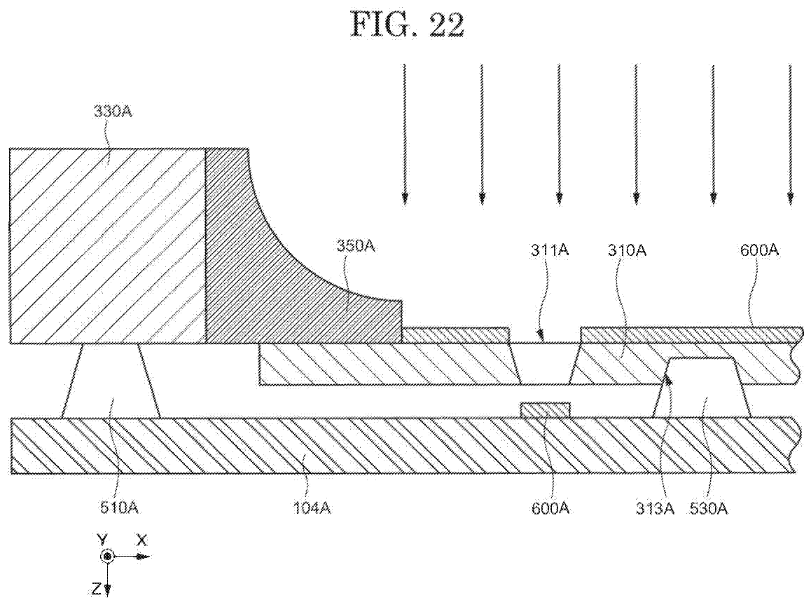

FIG. 22 is a cross-sectional view showing a method of forming a thin film on substrate 104A by vapor deposition in the vapor deposition process using the vapor deposition mask 300A according to the embodiment. The hole part 313A of the vapor deposition mask 300A and the alignment spacer 530A of the substrate 104A are aligned and fitted to each other. The vapor of the vapor deposition materials passes through the opening 311A from the second surface 310Ab side to the first surface 310Aa side (arrow, Z-direction) of the vapor deposition mask 300A, reaches the substrate 104A, and is deposited on the vapor deposition region, thereby forming the thin film 600A. The deposition materials are deposited on the second side 310Ab of the mask body 310A to form thin film 600A in the non-opening region 312A shielded by the mask body 310A. Since the hole part 313A is a bottomed hole, the thin film 600A is not formed on the alignment spacer 530A.

As described above, according to the vapor deposition method using the vapor deposition mask 300A according to the present embodiment, the alignment spacer 530A and the hole part 313A are fitted to each other, whereby the precision of the vapor deposition position and the productivity can be improved. In addition to the normal optical alignment marker, the physical alignment marker including the alignment spacer 530A and the hole part 313A according to the present embodiment can further improve the deposition position accuracy.

Each of the embodiments and the modification described above as an embodiment of the present invention can be appropriately combined and implemented as long as they do not contradict each other. Further, one embodiment of the present invention includes, as long as the gist of the one embodiment of present invention is provided, addition, deletion, or change of designs of constituent elements, or addition, omit, or change of condition of process, which are appropriately performed by a person skilled in the art based on the display device of the respective embodiments.

In this specification, the case of EL display device is mainly exemplified as the disclosed example, but other examples of application include any flat-panel type display device such as other self-luminous type display device, electronic paper type display device having electrophoretic elements and the like. In addition, one embodiment of the present invention can be applied from a medium-sized and small-sized to a large-sized, without any particular limitation.

Even if it is other working effects which differ from the working effect brought about by the mode of each above-mentioned embodiment, what is clear from the description in this Description, or what can be easily predicted by the person skilled in the art is naturally understood to be brought about by one embodiment of the present invention.

What is claimed is:

1. A vapor deposition mask comprising:
a mask body having a first surface and a second surface opposite to the first surface; and
a holding frame connected to the first surface;
wherein the mask body is arranged with a mask pattern region having at least one opening, and a peripheral region surrounding the mask pattern region and having at least one hole or concave part on the second surface side.

2. The vapor deposition mask according to claim 1, wherein an inner side surface of the at least one hole or concave part has a tapered structure in which a diameter of the second surface side is larger than a diameter of the first surface side.

3. The vapor deposition mask according to claim 1, wherein an inner side surface of the at least one opening has a reverse tapered structure in which a diameter of the first surface side is larger than a diameter of the second surface side.

4. The vapor deposition mask according to claim 1, wherein a depth of the at least one hole or concave part is half or more of a thickness of the mask.

5. The vapor deposition mask according to claim 1, wherein the at least one hole or concave part has a corner portion on the second surface.

6. The vapor deposition mask according to claim 1 wherein the at least one hole comprise a plurality of holes, and at least one concave part comprise a plurality of concave parts.

7. The vapor deposition mask according to claim 1, wherein
at least one hole or concave part includes a first hole or concave part and a second hole or concave part,
the first hole or concave part arranged in a center part of the mask body,
the second hole or concave part arranged in a peripheral part of the center part, and
a diameter of the first hole or concave part is larger than a diameter of the second hole or concave part on the second surface.

8. The vapor deposition mask according to claim 7, wherein the second hole or concave part is also arranged in the mask pattern region.

9. A method for manufacturing vapor deposition mask comprising:
forming a first resist pattern in a region corresponding to a mask pattern region of a substrate and a second resist pattern in a region corresponding to a peripheral region surrounding the mask pattern region of the substrate;
forming a mask body formed of a metal layer on the substrate, the mask body has at least one opening formed by the first resist pattern, and has at least one hole or concave part formed by the second resist pattern;
forming an insulating layer exposing an outer peripheral of the mask body and covering the at least one opening;
arranging a holding frame on the outer peripheral of the mask body;
forming a connecting member between the mask body and the holding frame;
removing the insulating layer; and
peeling the substrate from the mask body.

10. The method according to claim 9, wherein the second resist pattern is formed to have a tapered structure in which a cross-sectional area on the substrate side is larger than a cross-sectional area on the side opposite to the substrate.

11. The method according to claim 9, wherein the first resist pattern is formed to have a reverse tapered structure in which a cross-sectional area on the substrate side is smaller than a cross-sectional area on the side opposite to the substrate.

12. The method according to claim 9, wherein a height of the second resist pattern is formed to be half or more and less than 1 of a height of the first resist pattern.

13. The method according to claim 12, wherein the mask body is formed to cover the second resist pattern.

14. The method according to claim 9, wherein the second resist pattern is formed to have a corner portion in a plan view.

15. The method according to claim 9, the second resist pattern is formed as a plurality of second resist patterns.

16. The method according to claim 9, wherein the second resist pattern is also arranged in a region corresponding to the mask pattern region.

17. The method according to claim 9, wherein the mask body is formed by electrolytic plating method.

18. The method according to claim 9, wherein the first resist pattern and the second resist pattern are formed by photolithography method.

19. The method according to claim 9, wherein the second resist pattern is formed with a smaller exposure amount than that of the first resist pattern.
